(19) United States
(12) Patent Application Publication
(10) Pub. No.: US 2002/0149027 A1
(43) Pub. Date: Oct. 17, 2002

(54) SEMICONDUCTOR DEVICE AND ITS MANUFACTURE, AND SEMICONDUCTOR DEVICE PACKAGING STRUCTURE

(76) Inventors: NORIYUKI TAKAHASHI, YONEZAWA-SHI (JP); SEIICHI ICHIHARA, HINO-SHI (JP); CHUICHI MIYAZAKI, AKISHIMA-SHI (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/381,232

(22) PCT Filed: Mar. 19, 1998
(86) PCT No.: PCT/JP98/01182

(51) Int. Cl. H01L 23/495

(52) U.S. Cl. 257/100; 257/668; 257/678

(57) ABSTRACT

A semiconductor device comprising a semiconductor chip, a wiring substrate provided surrounding the semiconductor chip, leads projected from the wiring substrate and connected to the semiconductor chip, a stiffening member provided on one main surface of the wiring substrate, surrounding-the semiconductor chip, a plurality of bumps provided along a periphery of the wiring substrate on another main surface of the wiring substrate opposite to the main surface where the stiffening member is provided, and resin covering the semiconductor chip and the leads. The leads connected to the semiconductor chip are bend-processed toward a side where the stiffening member of the wiring substrate is provided or a side where the plurality of bumps are formed. The leads and the semiconductor chip are connected such that the surface of the semiconductor chip opposite to the surface connected to the leads is positioned on a side opposite to the side where the leads are bend-processed.

### TECHNICAL FIELD

The present invention relates to a semiconductor device and a method for manufacturing the semiconductor device and a semiconductor-device packaging structure, and more particularly to a BGA (Ball Grid Array) type semiconductor device and a method for manufacturing the semiconductor device and a semiconductor-device packaging structure, using a tape technique.

### BACKGROUND ART

A latest logic device must have a high operation speed and a number of functions by its high operation frequency and multi-bit signal. However, when the number of terminals increases in correspondence with such high speed operation and multiple functions, the size of an existing package, e.g., a package using a lead frame, increases due to the limitation of lead frame process. Then, the ratio of the area of the package with respect to a packaging substrate increases when the package is mounted on the packaging substrate. However, in recent years, downsizing and lightening are stressed in many of multimedia devices such as a communication device, a handheld-type personal computer, a camera-integrated VTR and a digital camera, while these devices have many functions.

From these current needs, improvement of LSI packaging technique, i.e., development of further downsized package in correspondence with multi-pin designing, is a significant object. A BGA type packaging technique to arrange solder balls as terminals for external connection in grid, on the rear surface of a package, has been proposed as a technique which particularly realizes downsizing of a plane dimension. As the first technique of the above packaging, a technique disclosed in Japanese Patent Application Laid-Open No. 8-88245 is known. As shown in FIG. 36, this technique provides a TAB type BGA characterized by comprising a base film 46 in which through holes 45 are formed, a copper foil wiring 48 formed on the base film, in which through holes 44 are formed, inner leads 47 connected to the copper foil wiring 48, a semiconductor chip bonded to the inner leads, seal resin sealing the semiconductor chip, and solder balls formed at the through holes 44. Further, as the second technique, a technique disclosed in Japanese Patent Application Laid-Open No. 8-88243 is known. As shown in FIG. 37, this technique provides a BGA type semiconductor device constructed by, in a TAB tape where a wiring pattern 53 covering via holes 50 is formed on one surface of an insulating film 52 with via holes 50 and a semiconductor chip is connected to inner leads of the wiring pattern 53, providing metal balls 51 connected to the wiring pattern 53 within the holes 50 from the opposite side to the wiring pattern side. Further, as the third technique, a technique disclosed in Japanese Patent Application Laid Open No. 8-111433 is known. As shown in FIG. 38, this technique provides a semiconductor device where through holes are formed in a base film member holding a semiconductor chip on its inner surface, and external connection electrode members 54, electrically connected to leads on the base film, are formed at the positions of the through holes, such that the electrode members project upward and downward from the front and rear surfaces of the base film; metal plates 55 are attached onto the upper parts of external connection electrode members 54, for connection between the lower parts of the external connection electrode members and a packaging substrate.

According to these first to third techniques, the plane dimension of the package is downsized, however, the thickness of the package is not reduced.

That is, as the number of terminals of the semiconductor chip increases, the plane dimension of the package increases. Accordingly, to prevent enlargement of the plane dimension of the package in spite of increase of the number of terminals, it is effective to provide external terminals in grid on the rear surface of the package. However, the plane dimension of the package is downsized by merely providing a number of external terminals on the rear surface of the package, whereas the thickness is not reduced. That is, the present inventor has pointed out that in the BGA type package shown in the first to third techniques, thinning of package is not sufficiently improved.

The present invention has an object to provide a semiconductor device having a thin package structure for multi-pin design and a method for manufacturing the semiconductor device.

Another object of the present invention is to provide a semiconductor device having a thin package structure with an excellent radiation characteristic, for multi-pin design, and a method for manufacturing the semiconductor device.

Another object of the present invention is to provide a semiconductor packaging structure which can be downsized and lightened.

Note that the above and other objects and novel features of the present invention will be apparent from the description of the present specification and the accompanying drawings.

### DISCLOSURE OF THE INVENTION

The outlines of representative ones of the inventions disclosed in the present application will be described as follows.

A semiconductor device comprising a semiconductor chip, a wiring substrate provided surrounding the semiconductor chip, leads projected from the wiring substrate and connected to toward semiconductor chip, a stiffening member provided on one main surface of toward wiring substrate, surrounding toward semiconductor chip, a plurality of bumps provided along a periphery of toward wiring substrate on an opposite main surface of toward wiring substrate to the main surface where toward stiffening member is provided, and resin covering toward semiconductor chip and the leads, wherein the leads connected to toward semiconductor chip are bend-processed toward a side where the stiffening member of toward wiring substrate is provided or a side where the plurality of bumps are formed, and wherein toward leads and toward semiconductor chip are connected such that a surface of toward semiconductor chip opposite to the surface connected to toward leads is positioned on a side opposite to the side where toward leads are bend-processed.

A semiconductor device comprising a semiconductor chip, a wiring substrate provided surrounding the semiconductor chip, leads projected from the wiring substrate and connected to toward semiconductor chip, a stiffening member provided on one main surface of toward wiring substrate, surrounding toward semiconductor chip, a plurality of bumps provided along a periphery of toward wiring substrate on an opposite main surface of toward wiring substrate to the main surface where toward stiffening member is provided, and resin covering toward semiconductor chip and the leads, wherein the total thickness of toward wiring substrate, the stiffening member and the plurality of bumps includes toward semiconductor chip and the leads connected to the semiconductor chip.

A semiconductor device comprising a semiconductor chip, a wiring substrate provided surrounding the semiconductor chip, a stiffening member provided on one main surface of toward wiring substrate, surrounding toward semiconductor chip, a plurality of bumps provided along a periphery of toward wiring substrate on an opposite main surface of toward wiring substrate to the main surface where toward stiffening member is provided, leads projected from the wiring substrate and connected to toward semiconductor chip, and resin covering toward semiconductor chip and the leads, wherein toward leads are bend-processed toward a side where toward plurality of bumps are provided, and wherein an another surface of toward semiconductor chip opposite to the surface connected to toward leads is positioned on a side where toward stiffening member is provided, further wherein a radiation plate is connected to the other surface of toward semiconductor chip and the surface of toward stiffening member.

A semiconductor-device manufacturing method comprising a step of preparing a band-shaped tape having a resin substrate, a device hole provided in the resin substrate and copper-foil leads projecting into the device hole and bend-processed, and a stiffening member connected to one main surface of toward tape, surrounding toward device hole, a step of connecting toward leads, projecting into the device hole of toward tape and bend-processed, to one main surface of a semiconductor chip, a step of sealing toward semiconductor chip and the leads with resin, a step of connecting a plurality of bumps to another main surface of toward tape opposite to the main surface where toward stiffening member is connected.

A packaging structure, comprising a print substrate having a main surface and another main surface opposite to the main surface, for packaging a plurality of semiconductor devices on the main surface and the other main surface of the print substrate, wherein a semiconductor device comprising a semiconductor chip, a wiring substrate provided surrounding the semiconductor chip, leads projected from the wiring substrate and connected to toward semiconductor chip, a stiffening member provided on the one main surface of toward wiring substrate, surrounding toward semiconductor chip, a plurality of bumps provided along a periphery of toward wiring substrate on the other main surface of toward wiring substrate opposite to the main surface where toward stiffening member is provided, and resin covering toward semiconductor chip and the leads, is packaged on toward main surface, such that the total thickness of toward wiring substrate, the stiffening member and the plurality of bumps includes toward semiconductor chip and the resin.

According to the above-described semiconductor device and the method for manufacturing the semiconductor device, the position of the semiconductor chip, viewed from a side direction to the semiconductor device, can be as center as possible of the semiconductor device. Thus, a thin semiconductor device for multi-pin design can be obtained.

Further, a thin semiconductor device with an excellent radiation characteristic, for multi-pin design, can be obtained.

Further, according to the above-described packaging structure, a packaging structure capable of downsizing, lightening and thinning can be obtained.

### BRIEF DESCRIPTION OF DRAWINGS

FIG. 1 is a plan view (front surface side) of a semiconductor device according to an embodiment 1 of the present invention;

FIG. 2 is a cross-sectional view cut along a line A-A′ in the semiconductor device in FIG. 1;

FIG. 3 is a plan view showing a wiring substrate used in the semiconductor device of the embodiment 1;

FIG. 4 is an enlarged view of a part “ [symbol] ” of the wiring substrate in FIG. 3;

FIG. 5 is a cross-sectional view cut along a line B-B′ in the wiring substrate in FIG. 4;

FIG. 6 is a significant-part enlarged cross-sectional view from FIG. 2;

FIG. 7 is a significant-part enlarged cross-sectional view showing a first another example of the semiconductor device in FIG. 1;

FIG. 8 is a significant-part enlarged cross-sectional view showing a second another example of the semiconductor device in FIG. 1;

FIG. 9 is a plan view (rear surface side) of the semiconductor device of the embodiment 1 of the present invention;

FIG. 10 is an enlarged view of a part “□” of the semiconductor device in FIG. 9;

FIG. 11 is a cross-sectional view cut along a line C-C′ in FIG. 10;

FIG. 12 is a cross-sectional flow diagram showing an example of a method for manufacturing the semiconductor device of the embodiment 1 of the present invention;

FIG. 13 is a plan view showing an example of a tape used in the method for manufacturing the semiconductor device of the embodiment 1 of the present invention;

FIG. 14 is a plan view of the tape in FIG. 13, wherein (a) is a significant-part enlarged plan view, and (b), a cross-sectional view cut along a line D-D′ in (a);

FIG. 15 is a partially enlarged view showing a first another example of the tape used in the method for manufacturing the semiconductor device of the embodiment 1 of the present invention;

FIG. 16 is a partially enlarged view showing a second another example of the tape used in the semiconductor device of the embodiment 1 of the present invention;

FIGS. 17(a) and 17(b) are partially cross-sectional views showing an example of offset process;

FIGS. 18(a) and 18(b) are partially cross-sectional views showing an example of a lead bonding method;

FIG. 19 is a conceptual view showing an example of a potting method;

FIG. 20 is a plan view showing the tape at a point where sealing process has been completed;

FIGS. 21(a) and 21(b) are plan views showing an example where the semiconductor device of the embodiment 1 is packaged on a print packaging substrate for a memory card, wherein (a) is a plan view on one surface side; and (b), a plan view on the opposite surface side;

FIG. 22 is a partially transparent plan view showing the memory card containing the print substrate for memory card in FIG. 21 in a case;

FIG. 23 is a cross-sectional view cut along a line E-E′ in the memory card in FIG. 22;

FIG. 24 is across-sectional view cut along a line F-F′ in the memory card in FIG. 22;

FIG. 25 is a plan view showing an example where the semiconductor device of the embodiment 1 is packaged on a print substrate for a multimedia device;

FIG. 26 is a plan view showing the semiconductor device according to an embodiment 2 of the present invention;

FIG. 27 is a cross-sectional view cut along a line G-G′ in the semiconductor device in FIG. 26;

FIG. 28 is a significant-part enlarged cross-sectional view from FIG. 27;

FIG. 29 is a cross-sectional view showing an example where the semiconductor device of the embodiment 2 is packaged, with another semiconductor device, on the print substrate;

FIG. 30 is a cross-sectional flow diagram showing an example of a method for manufacturing the semiconductor device of the embodiment 2;

FIG. 31 is a plan view showing the semiconductor device according to an embodiment 3 of the present invention;

FIG. 32 is a cross-sectional view cut along a line H-H′ in the semiconductor device in FIG. 31;

FIG. 33 is a significant-part enlarged cross-sectional view from FIG. 32;

FIG. 34 is a cross-sectional view showing an example where radiation fins are provided on a radiation plate of the semiconductor device of the embodiment 3;

FIG. 35 is a cross-sectional flow diagram showing an example of a method for manufacturing the semiconductor device of the embodiment 3;

FIG. 36 is a cross-sectional view showing the first conventional technique;

FIG. 37 is a cross-sectional view showing the second conventional technique; and

FIG. 38 is a flowchart showing an assembling process of the third conventional technique.

### BEST MODE FOR CARRYING OUT THE INVENTION

Hereinbelow, embodiments of the present invention will be described with reference to the drawings.

Note that in all the figures for explaining the embodiments of the present invention, elements having the same function have the same reference numeral, and repeated explanations for the elements will be omitted.

A semiconductor device according to the present invention is a BGA type semiconductor device comprising a plurality of ball-shaped solder bumps arrayed on one main surface (hereinafter referred to as a rear surface) of the semiconductor device, as external terminals, and using a tape technique for connection between a pads of a semiconductor chip and the external terminals.

(Embodiment 1)

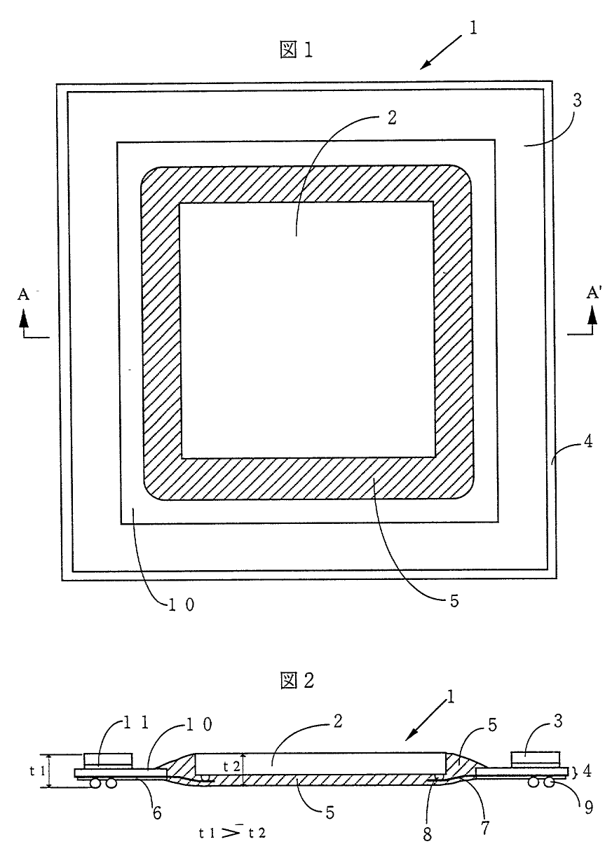

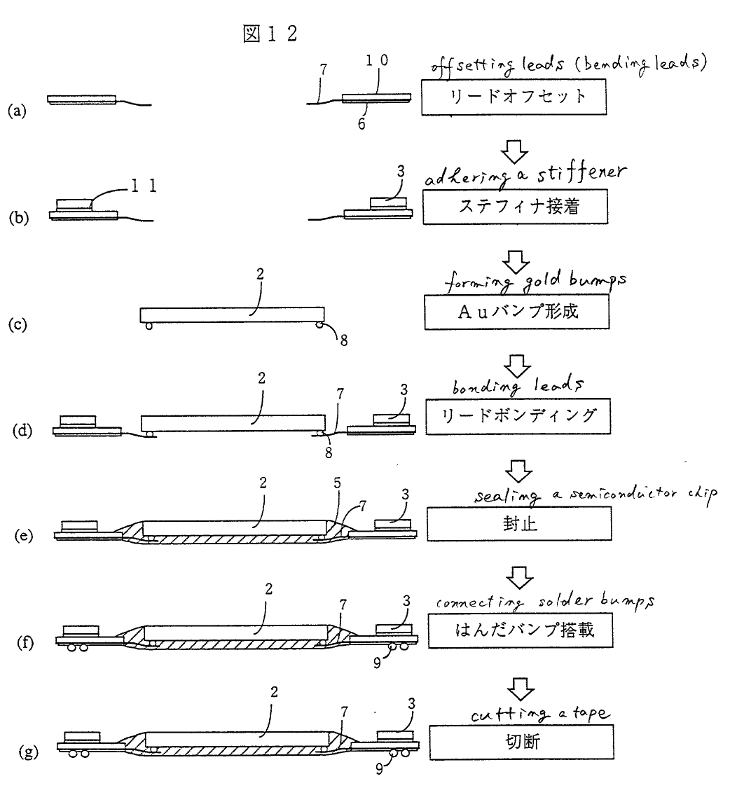

First, the structure of a semiconductor device according to an embodiment 1 of the present invention will be described by using FIGS. 1 to 11.

As shown in FIGS. 1, 2 and 9, a semiconductor device 1 of the embodiment 1 has a plurality of arrayed ball-shaped solder bumps 9, as external terminals for connection to a packaging substrate (not shown). The ball-shaped solder bumps 9 are formed on a frame-shaped wiring substrate 4 having a substrate 10 of polyimide resin and leads 7 as copper-foil wiring formed thereon. As the material of the substrate 10, polyimide resin, glass epoxy, BT (Bismaleimide-Triazine) resin, or PET (Polyethylene terphthalate) and the like are used.

Then, to improve the mechanical strength of the semiconductor device 1, a frame-shaped stiffening member (hereinafter referred to as a stiffener 3) with a thickness of about 200 μm, having a hole capable of containing a semiconductor chip within a plane, is connected along the periphery of the wiring substrate 4 by using epoxy resin adhesive 11 with a thickness of about 50 μm, on the surface of the wiring substrate 4 opposite to the surface where the leads 7 on the substrate 10 are formed. Beside the epoxy resin, polyimide resin may be employed as the adhesive 11.

The material of the stiffener 3 is preferably material having a thermal expansion coefficient close to that of the packaging substrate on which the semiconductor device 1 is packaged. For example, Cu or a Cu alloy including Cu as a main component, Al or an Al alloy, or an iron alloy or ceramics are preferable. The shape of the stiffener is not limited but any shape is available as long as it can surround a semiconductor chip 2, as shown in FIG. 1.

In the semiconductor chip 2, a predetermined integrated circuit such as a microcomputer or an ASIC and pads (not shown) of Al or the like as terminals for external connection of the circuit are provided on one main surface of a semiconductor substrate of silicon or the like having a thickness of, e.g., about 400-550 μm, and, a passivation film for protecting the integrated circuit is formed on the top layer of the integrated circuit forming surface. The passivation film comprises polyimide resin having a thickness of, e.g., about 2-10 μm.

The passivation film has an opening where Au bumps 8 to be connected to the above pad are formed. The diameter of the Au bumps 8 is about 14-35 μm. The Au bump 8 comprises a plate bump or a wire bump. Note that the Au bumps 8 may be formed on the side of the leads 7 on the wiring substrate 4.

As shown in FIG. 2, the semiconductor chip 2 is provided such that the main surface where the integrated circuit and the Au bumps 8 are formed is facing the rear surface side of the semiconductor device 1, i.e., the side where the solder bumps 9 are formed, and connected to the leads 7, projected from the wiring substrate 4 and bend-processed (offset-processed) in advance to the rear surface side of the semiconductor device 1, i.e., the side where the solder bumps 9 are formed. Then, the main surface where the integrated circuit of the semiconductor chip 2 is formed, the side surfaces and the leads 7 are sealed with sealing resin 5 for the purposes of protection of the semiconductor device 1, improvement of moisture resistance, and improvement of reliability in the junction portion between the leads 7 and the semiconductor chip 2. As the resin 5, silicone resin, epoxy resin or the like is used.

As shown in FIG. 2, the semiconductor device 1 is arranged such that a total thickness t1 of the solder bumps 9, the wiring substrate 4 and the stiffener 3 is greater than a total thickness t2 of the semiconductor chip 2 and the sealing resin 5 (t1>t2). In other words, the total thickness t2 of the semiconductor chip 2 and the sealing resin 5 is included in the total thickness t1 of the solder bumps 9, the wiring substrate 4 and the stiffener 3.

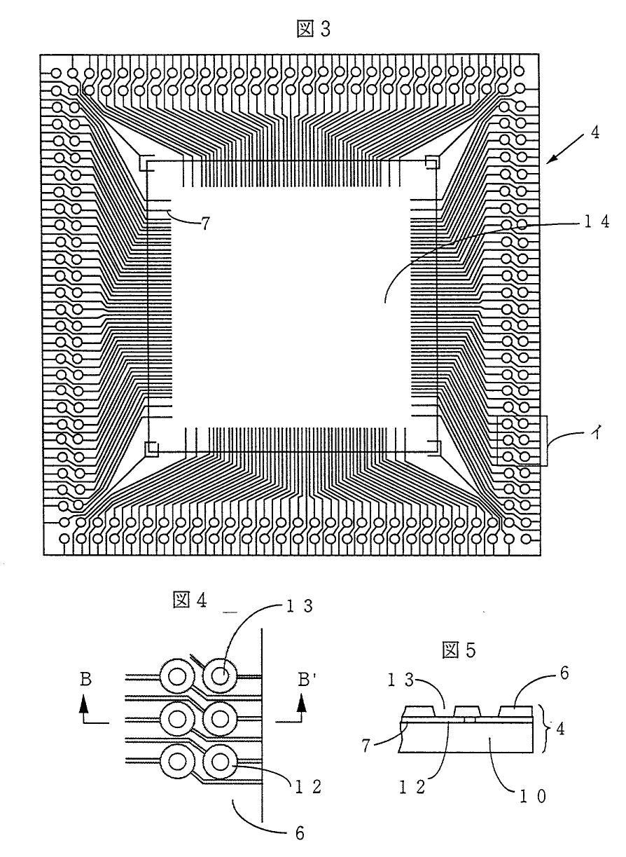

Next, the details of the above-described semiconductor device 1 will be described based on FIGS. 3 to 11.

The above-described wiring substrate 4 is a member for electrically connecting the Au bumps 8 of the semiconductor chip 2 to the solder bumps 9. As shown in the plan view of FIG. 3, a device hole 14 is formed through the wiring substrate 4 at the central portion of the substrate. The device hole 14 is capable of containing the semiconductor chip 2. The wiring substrate 4 has the substrate 10 having a thickness of about 50-125 μn or preferably 75±8 μm, the leads 7 of an arbitrary wiring pattern comprising copper foil having a thickness of about 12-30 μm or preferably 18±2 μm, and bump lands 12 each having a disk-shaped flat surface, formed on one main surface of the substrate 10. These leads 7 and the pump lands 12 are attached to the substrate 10 by adhesive (not shown) having a thickness of about 12±4 μm. Further, the leads 7 and the bump lands 12 are covered with a photosensitive insulating film 6 such as solder resist. The photosensitive insulating film 6 is an insulating film of melamine, acryl, polystyrol, polyimide, polyurethane, silicone or the like, having-a thickness of 5-30 μm or preferably 20 μm. The insulating film 6 preferably has thermal resistance to tolerate a soldering temperature and a characteristic that it is not soaked with solder, further, a characteristic that it prevents deterioration of the wiring substrate due to moisture or contamination and further tolerates exposure of flux or cleaning liquid.

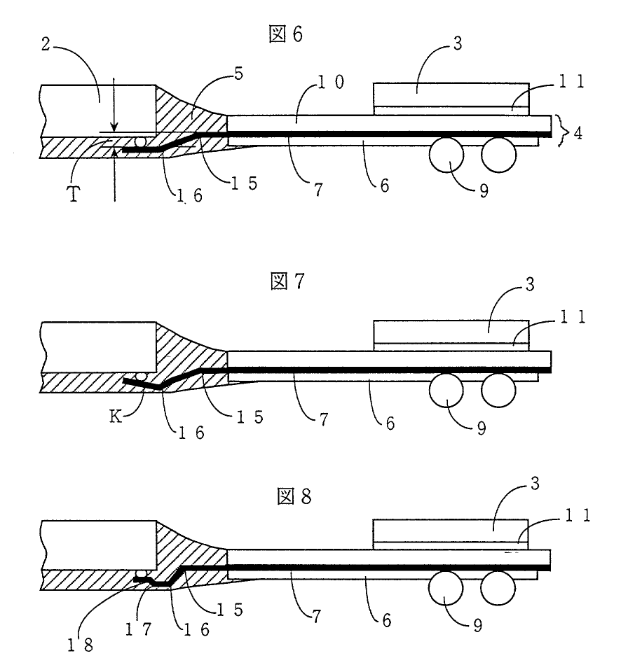

The above-described bump lands 12 are regularly provided along the outer periphery of the wiring substrate 14. For example, in the embodiment 1, the bump lands having a diameter of 310 μm are provided at a pitch (interval) of 500 μm, along the periphery of the wiring substrate 4, in two lines, a periphery-side line and an inner line. However, the diameter, pitch and arrangement of the bump lands differ by product and are not limited to the above diameter, pitch and arrangement. For example, the diameter may be 300-500 μm, the pitch may be 500-800 μm, and the arrangement pattern may be regularly two or three lines, or may be irregularly provided. Further, as shown in FIGS. 4 and 5, a part of the bump lands 12 are exposed through openings 13 formed in the photosensitive insulating film 6 by a photolithographic technique, and the exposed bump lands 12 are connected to =the solder bumps. In case of forming the openings by the photolithographic technique, fine process is possible in correspondence with miniaturization of the solder bumps.

The formation of the openings in the photosensitive insulating film 6 on the substrate 10 may be made by a mechanical process method such as punching. Note that in this case, as the diameter of the opening is limited, this method is not appropriate for fine process.

In FIG. 3, the photosensitive insulating film is omitted for the sake of convenience of illustration.

A part of the leads 7 as the wiring pattern formed with copper foil project into the device hole 14 of the wiring substrate 4. In the wiring substrate 4, viewed from its side direction, the positions of the respective projecting leads are substantially within the same plane. This plane is referred to as a lead projection plane.

The semiconductor chip 2 is provided in the device hole 14, with the main surface where the integrated circuit and the Au bumps 8 are formed facing the rear surface side of the semiconductor device 1, i.e., the side where the solder bumps 9 are formed (hereinafter referred to as face down), and the Au bumps 8 are electrically connected to the leads 7 projected in the device hole 14.

FIG. 6 is a significant-part enlarged cross-sectional view from FIG. 2. As shown in FIG. 6, the leads 7 projected in the device hole 14 respectively have a first bend portion 15 bend-processed toward a direction away from the rear surface side of the semiconductor device 1, i.e., the side where the solder bumps 9 are formed or the side connected to the leads 7 of the semiconductor chip 2, and a second bend portion 16 bend-processed so as to form a region parallel to a device formation surface of the semiconductor chip 2 on the lead tip side from the first bend portion 15. This bend-processed lead structure is called an offset structure. The offset amount of the structure (the distance between the first bend portion 15 and the second bend portion 16, in other words, the distance between the position of the lead 7 on the substrate 10 and the position of the lead 7 changed by the first bend portion 15) is denoted by T.

The connection between the leads 7 and the Au bumps 8 is made in a region from the second bend portions 16 to the tips of the leads 7.

In the embodiment 1, in consideration of the thickness of the semiconductor chip and the diameter of the solder bump, the offset structure and the offset amount T are set to 125 μm such that the semiconductor device 1 has the minimum thickness. However, as the offset amount T and the offset structure depend on the thickness of the semiconductor chip, the diameter of the solder ball and the like, and differ by each product, they are not limited to the above value.

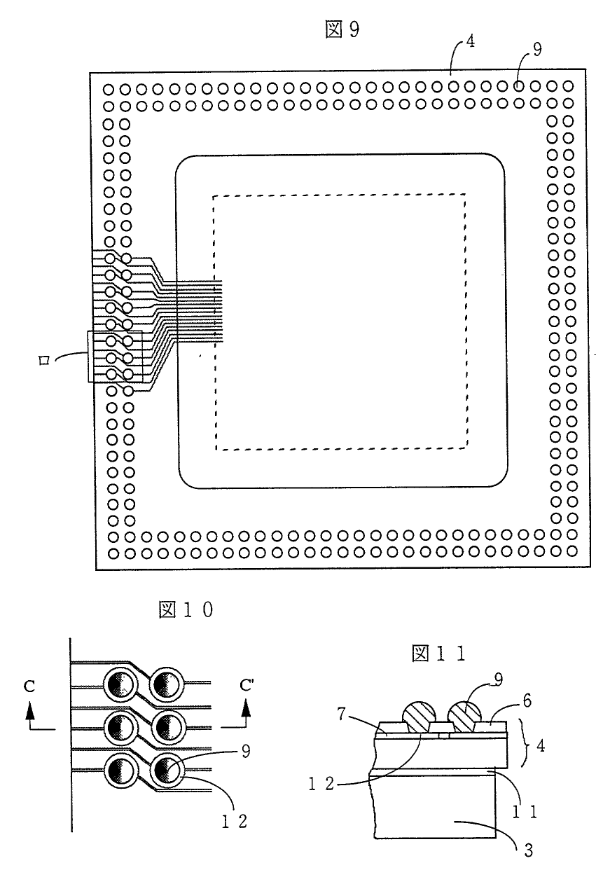

For example, as shown in FIG. 7, it may be arranged such that the lead has a slope K which gradually approaches the device formation surface of the semiconductor chip from the second bend portion 16 to the lead tip, in other words, gradually moves away from the device formation surface of the semiconductor chip from the connection portion with the Au bump 8 toward the second bend portion 16. This prevents contact between the periphery of the device formation surface of the semiconductor chip which cannot be easily coated with the passivation film and the leads (hereinafter referred to as edge short). Further, as shown in FIG. 8, it may be arranged such that the lead has a first bend portion 15 bend-processed toward the rear surface side of the semiconductor device from the lead projection direction around the wiring substrate, a second bend portion 16 bend-processed to have a first region parallel to the device formation surface of the semiconductor chip on the lead tip side from the first bend portion 15, a third bend portion 17 and a fourth bend portion 18 bend-processed so as to form a second region parallel to the device formation surface of the semiconductor chip on the semiconductor chip 2 side from the above first region on the lead tip side from the second bend portion 16. This prevents the edge short between the periphery of the device formation surface of the semiconductor chip and the leads and contact between the device formation surface of the semiconductor chip and the lead tip portions. Note that in both structures in FIGS. 7 and 8, the second to fourth bend portions are formed within a range not to reach the position of the lead 7 on the substrate 10 so as to ensure the above offset amount.

As shown in FIGS. 9 to 11, in the semiconductor device, the solder bumps 9 are connected to the bump lands 12 exposed through the openings formed in the solder resist of the wiring substrate 4 as terminals for connection with the packaging substrate. The solder bump 9 is a ball bump having a diameter of about 300 μm, comprising materials such as Pb—Sn and an alloy including Pb—Sn as the main component. The solder bumps 9 are arranged along the periphery of the wiring substrate 4, at a pitch of 500 μm, in two lines, the periphery side line and the inner line. As described above, as the openings of the solder resist can be small, and the solder bumps 9 can be miniaturized, thus the semiconductor device can be thinned. However, the material, diameter, pitch and arrangement pattern of the solder bumps differ by each product and are not limited to the above. For example, the diameter may be 300-500 μm, the pitch may be 500-800 μm, and the arrangement pattern may be regularly two lines or three lines, or may be irregularly provided.

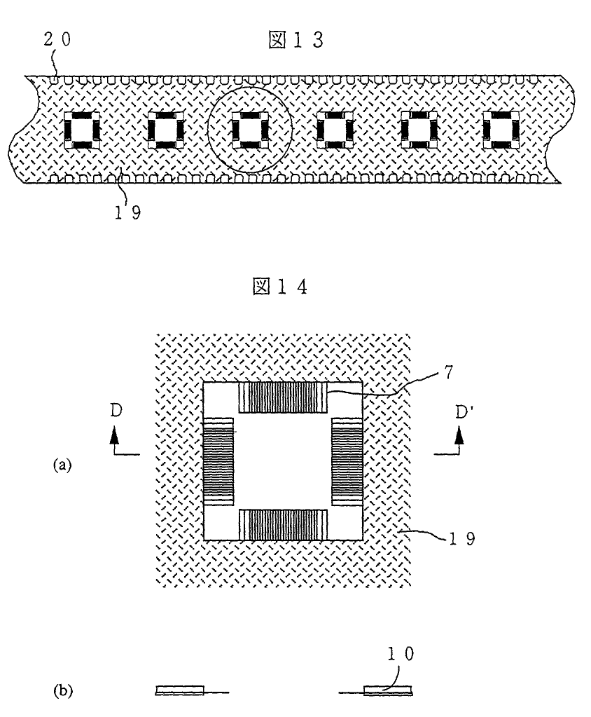

Next, an example of the method for manufacturing the semiconductor device of the embodiment 1 will be described by using the cross-sectional flow diagram of FIG. 12 and FIGS. 13 to 20.

Prior to the manufacture of the semiconductor device, as shown in FIG. 13, the respective constituents of the semiconductor devices, a band-shaped tape 19 (this tape 19 is processed and cut into the wiring substrates 4) having the substrates 10 of, e.g., polyimide resin, the leads 7 of an arbitrary wiring pattern formed with copper foil on one main surface of the substrates 10, the photosensitive insulating films 6 covering the wirings, a plurality of device holes 14 formed through the substrates 10, and the leads 7 projecting into the device holes 14, the stiffeners 3 having a hole capable of containing the semiconductor chip within a flat plane, the semiconductor chips 2 having one main surface where the integrated circuit and the pads are formed, the sealing resin, the flux, solder balls and the like, are prepared.

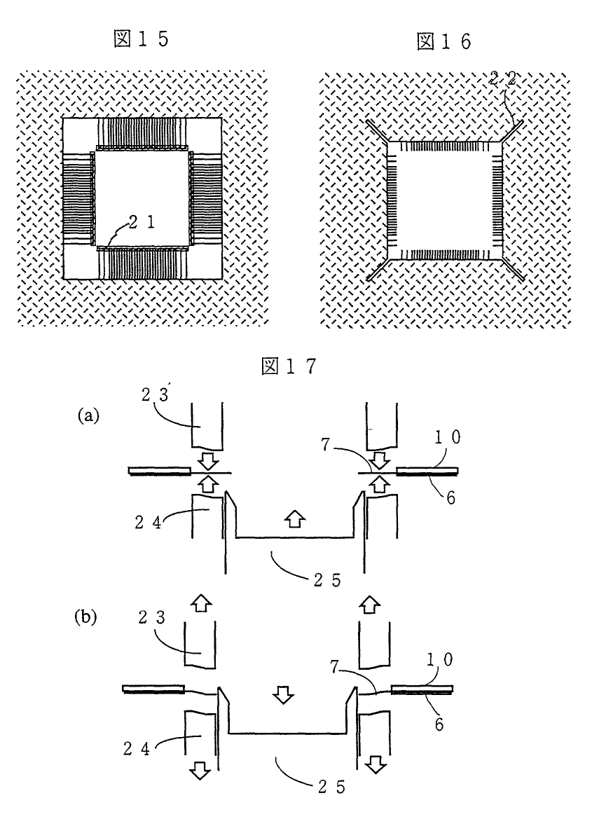

FIG. 14(a) is a significant-part enlarged plan view from FIG. 13. FIG. 14(b) is a cross sectional viewcut along a line D-D′ in (a). As it is understood from these figures, the leads before they are processed are formed in the same plane of the wiring on the substrate 10, with the end portions integrally connected to each other.

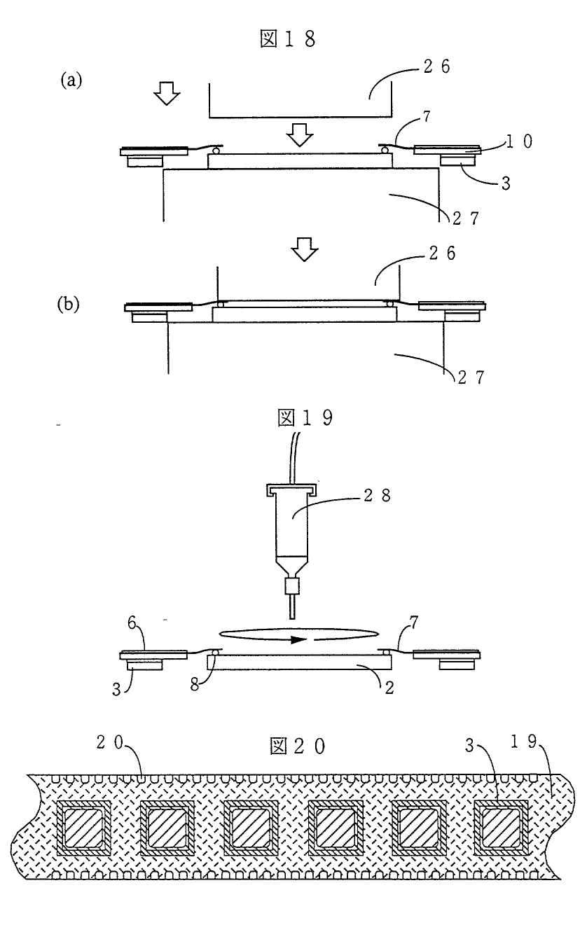

First, as shown in FIG. 12(a), the leads 7 projecting into the device hole 14 from the substrate 10 of the tape 19 are bend-processed toward the side of the tape 19 where the solder bumps 9 are formed. As described above, the unprocessed leads 7 are formed in the same plane of the wiring on the substrate 10, with the end portions integrally connected to each other. This suppresses variation in shapes of the lead tip portions. As shown in FIG. 15, the integrally-connected lead tip portions may be reinforced with a fixing member 21 such as a tape. Further, as shown in FIG. 16, the substrate 10 may extend closer to the projected lead end portions, and the extended substrate 10 may have four slits 22 allowing the leads to be bend-processed.

The unprocessed leads have a relatively long lead length so as to enable connection with semiconductor chips of different outer dimensions. By this arrangement, even in a case where the lead end positions must be changed in accordance with the outer dimension of the semiconductor chip, the leads have the sufficient length. Therefore, it is unnecessary to prepare a different tape each time the outer dimension of the semiconductor chip changes.

The lead process is performed as follows. First, as shown in FIG. 17(a), the leads positioned in a plane are inserted between a die 24 and a punch 23 as lead shaping tools. Thereafter, as shown in FIG. 17(b), the die 24 and the punch 23 are struck vertically toward the leads 7 to shape the leads into a predetermined shape, and the end portions of the leads 7 are cut by a cutting punch 25 into a predetermined length appropriate to the semiconductor chip. Note that the connected lead end portions are separated into individual end portions. Hereinafter, these processes will be called offset process and lead offset process. Further, at a process of preparing the constituents of semiconductor devices, a tape where the leads are offset-processed in advance may be prepared (process a).

Next, as shown in FIG. 12(b), the stiffener 3 is attached by heat pressing via adhesive 11 of epoxy resin or the like, along the device hole on the substrate 10 of the band-shaped tape 19, processed at the lead offset process. Hereinafter, this process will be called a stiffener attachment process (process b).

Next, as shown in FIG. 12(c), the Au bumps 8 are formed by, e.g., a ball bonding method, on the pads formed on one main surface of the semiconductor chip 2. The bump formation may be made by plating. Hereinafter, this process will be called an Au bump formation process (process c).

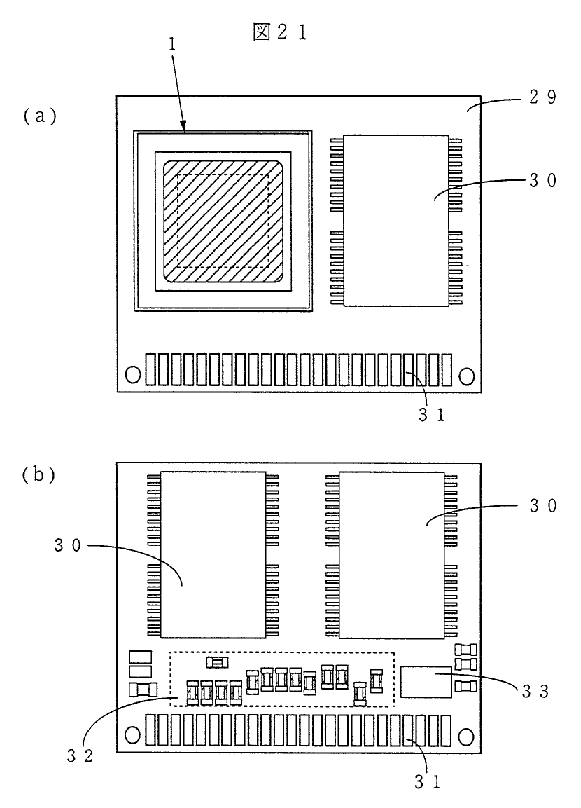

Next, as shown in FIG. 12(d), the Au bumps 8 on the semiconductor chip 2 are electrically connected to the leads 7. At this process, as shown in FIG. 18(a), the semiconductor chip 2 is mounted on a bonding stage 27 such that the surface where the Au bumps 8 are formed faces upward. Then, the tape 19 is positioned on the semiconductor chip 2 such that the leads 7 projected from the substrate 10 of the tape 19 and the Au bumps 8 of the semiconductor chip 2 are opposite to each other, and the semiconductor chip 2 and the tape 19 are aligned such that the Au bumps 8 on the semiconductor chip 2 and the positions of the connection portions around the end portions of the leads 7 of the tape 19 correspond with each other. At this time, it is preferable that the distance between the respective leads 7 and the Au bumps 8 is as short as possible. Further, the tape 19 is positioned such that the surface where the stiffener 13 is formed is on the semiconductor chip 2 side.

Thereafter, as shown in FIG. 18(b), a bonding tool 26 is vertically struck toward the main surface side of the semiconductor chip 2, while the above positional relation is maintained and the tape 19 is fixed so as not to move by tape guides (not shown), to press and connect the leads 7 and the Au bumps 8 (hereinafter called a simultaneous bonding). At this time, it is significant that the connection is made such that the positional relation with the tape 19 does not change. For example, the amount of pressing by the tool is preferably a value less than the diameter of the Au bump. Even when the number of pins is large, bonding can be made at once by the simultaneous bonding, accordingly, time necessary for bonding is short regardless of the number of pins. In this bonding, it is significant that the leads 7 and the Au bumps 8 are uniformly heat-pressed. For this purpose, the flat shape of the leads 7 must be ensured. In the embodiment 1, as described above, the tip portions of the reads 7 are integrally formed and separated for the respective leads at the lead offset process, thus the flat shape can be maintained while preventing variation of the leads. Hereinafter, this process will be called a lead bonding process (process d).

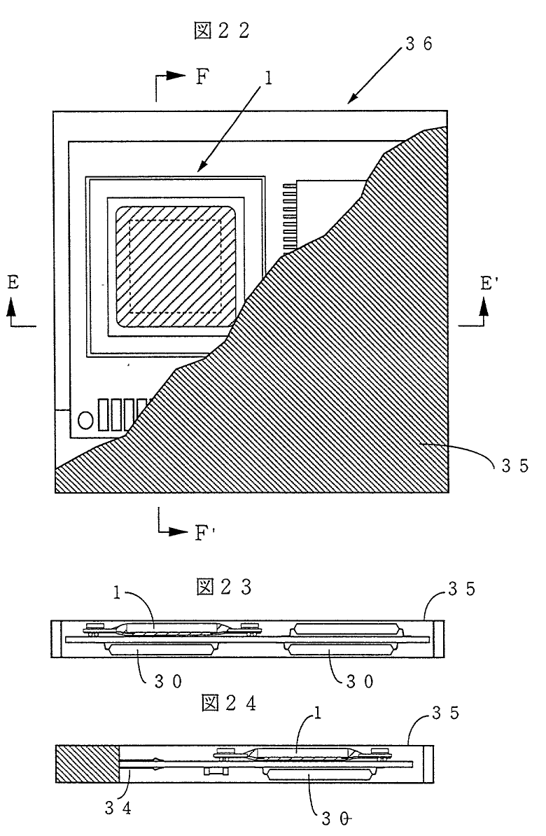

Next, as shown in FIG. 12(e), the main surface of the semiconductor chip 2, where the integrated circuit is formed, the side surfaces and the leads 7 are sealed with liquid resin 5 by potting. As shown in FIG. 19, the sealing resin 5 is dropped from a dispenser 28, which is movable as represented with a looped arrow in FIG. 19, on the main surface of the semiconductor chip 2 and the leads 7, to seal the main surface and the side surfaces of the semiconductor chip 2 and the leads 7, while the main surface of the semiconductor chip 2 where the integrated circuit is formed faces up. At this time, the interval between the leads 7 and the side surfaces of the semiconductor chip 2 are filled with resin by the surface tension of the resin. Hereinafter, this process will be called a sealing process (process e).

Next, as shown in FIG. 12(f), the ball-shaped solder bumps 9 comprising material such as Pb—Sn are connected to the bump lands exposed through the openings formed in the photosensitive insulating film of the tape 19. First, the solder bumps are aligned with the bump lands within a plane and sucked by a mounting tool (not shown). Then, the solder bumps sucked by the mounting tool are coated with the flux, and the solder bumps 9 coated with the flux are connected to the bump lands of the semiconductor device, at once, by the mounting tool. Hereinafter, this process will be called a solder bump mounting process (process f).

Next, as shown in FIG. 12(g), the band-shaped tape 19 in a state as shown in FIG. 20 where the solder bump mounting process has been completed is cut, at a position slightly outer from the periphery of the stiffener 3. Thus, the semiconductor device is cut out into one piece. Hereinafter, this process will be called a cutting process (process g).

Thereafter, a predetermined examination is performed on the semiconductor device to determine whether it is good/no good. Thus, the manufacture of the semiconductor devices is completed.

Note that the connection between the leads 7 and the Au bumps 8 at the lead bonding process (process d) is not limited to the simultaneous bonding. For example, the connection may be made by heating the semiconductor chip heated on a bonding stage by a heater, and applying an ultrasonic wave to a bonding tool and pressing the tool, to connect the leads to the Au bumps of the semiconductor chip, by single point (hereinafter referred to as a single-point bonding method). In a case where the bonding tool differs by each type of semiconductor chip and the bonding tool must be frequently exchanged for another type of bonding tool, the working efficiency of the simultaneous bonding is low. However, the single-point bonding method, which unnecessitates exchange of the pointing tool and enables easy type exchange, is preferably applicable to a little-amount and multiple-chip type product such as an ASIC.

Further, the sealing at the sealing process (process e) is not limited to the potting, but it may be made by transfer molding. The transfer molding is sealing a semiconductor chip and leads by: first setting a tape, where offset-processed leads are connected to a semiconductor chip, between a first mold and a second mold for molding, such that the semiconductor chip is included in a cavity formed on the surfaces of the respective molds; then, closing the first mold and the second mold; and supplying sealing resin via a gate into the cavity. In this transfer molding, as the resin serves as a stiffener which is a reinforcement member of the semiconductor device, the stiffener is not necessary. Accordingly, the manufacturing cost of the semiconductor device is reduced.

Next, an example where the semiconductor device 1 of the embodiment 1 is packaged on the packaging substrate will be described.

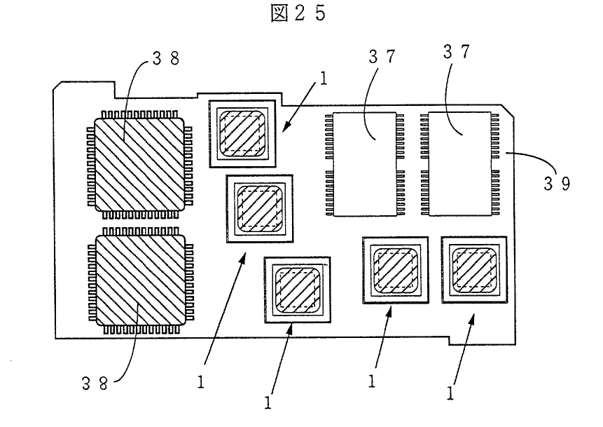

First, an example where the semiconductor device 1 of the embodiment 1 of the present invention is applied to a small memory card will be described by using FIGS. 21 to 24.

FIG. 21 is a plan view showing an example where the semiconductor device 1 of the embodiment 1 is packaged on a print substrate 29 for a small memory card, wherein (a) is a plan view on one surface side; and (b), a plan view on the opposite surface side.

As shown in FIG. 21(a), the semiconductor device 1 of the embodiment 1 of the present invention and a memory 30 using a TCP (Tape Carrier Package) or a TSOP (Thin Small Out-line Package)-type thin package are packaged on one surface of the print substrate 29. Further, as shown in FIG. 21(b), a plurality of memories 30 using a thin package similar to the above package are packaged on the other surface of the print substrate 29. Further, a crystal oscillator 33 and a plurality of chip parts 32 such as a chip condenser and a chip resistor are also packaged on the other surface of the print substrate 29.

Then, as shown in FIG. 22, the print packaging substrate 29 is connected to a print substrate socket 34 via external terminals 31, then the print substrate socket 34 and the print substrate 29 are set in a case 35, thus constructing a small memory card 36.

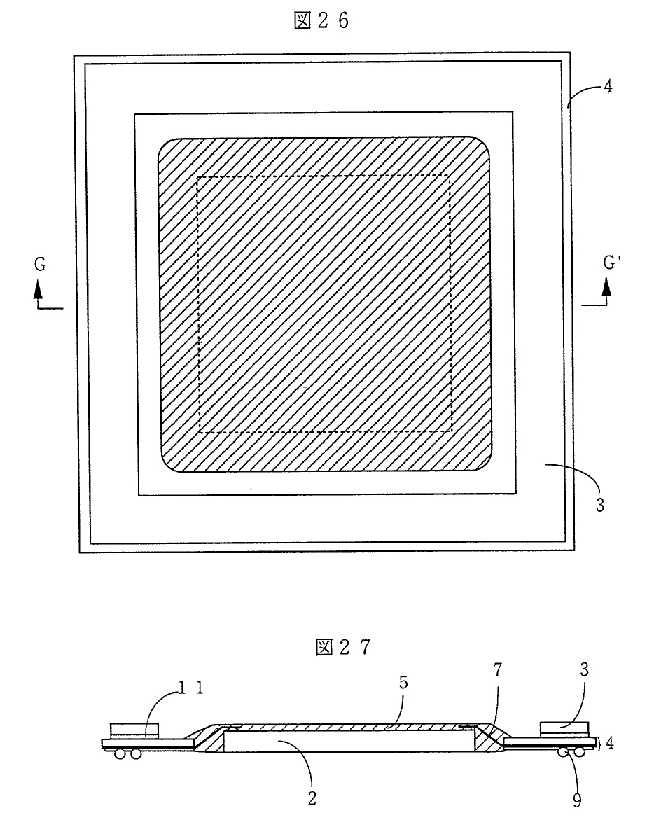

FIG. 23 is a cross-sectional view cut along a line E-E′ in the memory card 36 in FIG. 22. FIG. 24 is a cross-sectional view cut along a line F-F′ in the memory card 36 in FIG. 22.

In the semiconductor device 1 of the embodiment 1 used in the small memory card 36, an integrated circuit (integrated circuit having functions as a microcomputer, a gate array and the like) is formed for controlling the above memories 30 and data transfer between the host microcomputer and the memories 30.

Further, the memories 30 formed on one surface and the other surface of the print substrate 29 are nonvolatile memories for semi-eternally storing data or volatile memories used for storing memory card control programs and the like. As the nonvolatile memories, a flash memory, an EEPROM (Electrically Erasable and Programmable Read Only Memory), an EPROM (Erasable and Programmable Read Only Memory), a mask ROM and the like are used. Further, as the volatile memories, a DRAM, an SRAM and the like are used.

The solder bumps 9 on the rear surface of the semiconductor device 1 of the embodiment 1 are electrically connected to wiring (not shown) on the print substrate 29 Further, the lead portions of the TCP or TSOP memories 30 are electrically connected to the wiring on the print substrate 29.

Further, it may be arranged such that two of the semiconductor devices 1 of the present embodiment are used as a device having a microcomputer function and a device having a gate array function, and the semiconductor devices 1 are packaged on one surface of the print substrate 29. In this case, one of the plurality of memories 30 packaged on the other surface of the print substrate 29 is a nonvolatile memory, while another one is a volatile memory.

In this memory card 36, as the thin semiconductor device 1 as in the embodiment 1 is employed as a high-performance and multi-pin semiconductor device as a controller (device having a function of microcomputer or gate array or both functions) which has not been conventionally thinned without difficulty, the memory card 36 can be downsized and lightened, further, greatly thinned. Further, as the semiconductor device 1 of the embodiment 1 is of surface package type, it can be packaged with semiconductor devices of other surface package types such as TCP type, TSOP type and UTSOP type, on the same packaging substrate, and they are reflow-processed at once. This facilitates packaging.

The small memory card 36 is very useful when it is employed as a compact card used in a digital camera or the like.

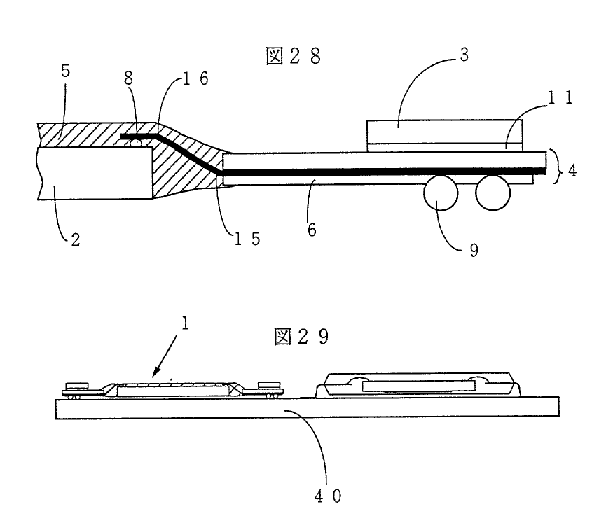

Next, an example where the semiconductor device 1 of the embodiment 1 is applied to a print substrate 39 for a multimedia device will be described by using FIG. 25. FIG. 25 is a plan view showing an example where the semiconductor device 1 of the embodiment 1 is packaged on the print substrate 39 for multimedia device.

As shown in FIG. 25, a plurality of semiconductor devices 1 of the embodiment 1, and a plurality of QFP (Quad Flat Package)-type semiconductor devices 38 and TCP-type or TSOP-type semiconductor devices 37, are packaged on the surface of the print substrate 39. The semiconductor device 1 of the embodiment 1 is constructed by forming an integrated circuit such as a microcomputer, a gate array or-the like.

The solder bumps 9 on the rear surface of the semiconductor device of the embodiment 1 are electrically connected to wiring on the print substrate 38. Further, the lead portion of the QFP-, TCP- or TSOP-type semiconductor device 37 is electrically connected to the wiring on the print substrate 39.

In the print substrate 39, the packaging density is improved by employing plural semiconductor devices 1 of the embodiment 1, thus the area of the print substrate 39 is reduced, and the substrate is lightened. The small print substrate 39 is installed into a camera-integrated VTR, a handheld personal computer and the like, thus greatly contributing to high performance, portability and lightening of the products. Further, as the semiconductor device 1 of the embodiment 1 is of surface package type, it can be mounted with other semiconductor devices such as QFP-, TCP- or TSOP-type surface package type semiconductor devices on the packaging substrate, and they are reflow-processed at once. This facilitates packaging.

Next, the effects of the embodiment 1 as described above will be given.

The above-described semiconductor device 1 of the embodiment 1 obtains the following effects.

(1) The position of the chip viewed from the side surface of the semiconductor device 1 can be as center as possible of the semiconductor device 1. That is, the semiconductor device 1 can be constructed such that the total thickness of the solder bumps 9, the wiring substrate 4, the leads 7 on the wiring substrate 4, the stiffener 3 and the adhesive 11, includes the semiconductor chip 2, the Au bumps 8 and the leads 7 connected to the Au bumps 8. This attains thinning of the semiconductor device 1.

For example, if the diameter of the solder bumps 9=300 μm, the wiring substrate 4=87 μm, the thickness of the leads 7=18 μm, the stiffener 3=200 μm, the adhesive 11=50 μm, the thickness of the semiconductor chip 2=400 μm, and the height of the Au bumps=35 μm, the thickness of the semiconductor device 1 is 655 μm.

As described above, in the semiconductor device of the embodiment 1, as the thickness of the final structure of the semiconductor device can be extremely thin by employing the offset structure for the leads, a thin and multi-pin semiconductor device can be obtained.

(2) As the tape 19, where the leads 7 of the wiring pattern are formed on the substrate 10 of polyimide resin or the like, is used as connection means for connection with the semiconductor chip 2, high productivity is attained, and the semiconductor device can be assembled at a low cost.

(3) As the solder bumps 9 for connection between the semiconductor device 1 and the packaging substrate are connected on the side of the wiring substrate 4 where the leads 7 are formed, it is unnecessary to form through holes and multilayer wiring. Thus, the semiconductor device can be manufacture at a low cost.

(4) As the solder bumps 9 for connection between the semiconductor device 1 and the packaging substrate are two-dimensionally arranged on the rear surface of the semiconductor device 1, multi-pin structure can be obtained without increasing the area of the semiconductor device.

(5) The leads 7 can be offset-processed with high precision by performing the offset-processing when the leads 7 are in the form of member.

(6) As the length of the leads 7 of the wiring substrate 4 is relatively long, and the tip portion of the leads 7 is cut in correspondence with the outer dimension of the semiconductor chip 2, the leads can be used for semiconductor chips of different outer dimensions, which reduces the manufacturing cost of the semiconductor device 1.

(7) As the semiconductor device 1 is of surface package type, it can be mounted with semiconductors of other surface package types such as QFP-, TSOP-, UTSOP- and TCP-types on the same packaging substrate, and they can be reflow-processed at once.

(8) The packaging structure to package the semiconductor device on the print substrate can be downsized, lightened and thinned.

(Embodiment 2)

First, the structure of the semiconductor device according to an embodiment 2 will be described by using FIGS. 26 to 28.

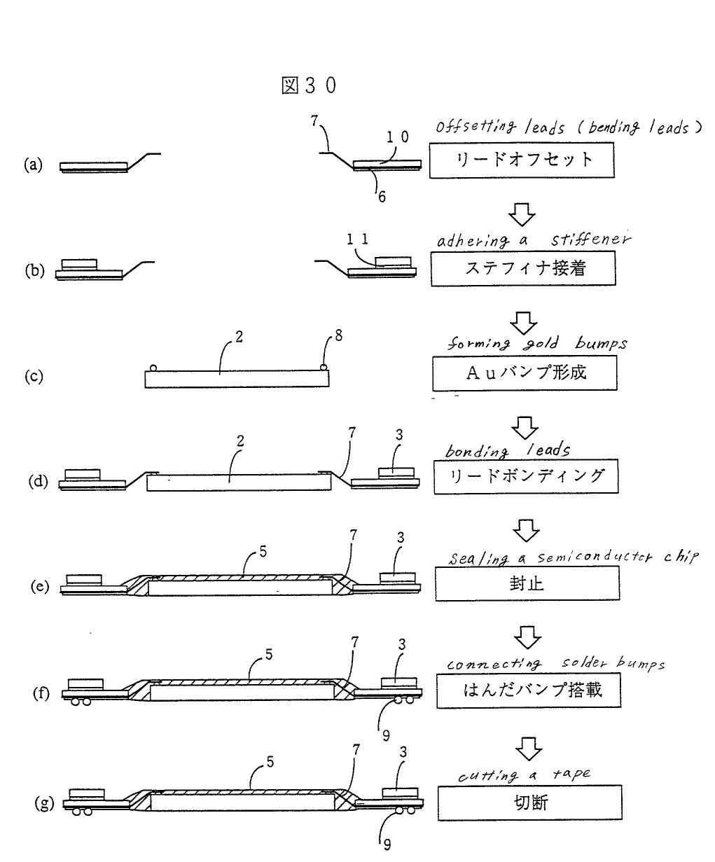

The semiconductor device of the embodiment 2 is a BGA type semiconductor device where the leads 7 of the wiring substrate 4 are offset-processed, similarly to the embodiment 1. The difference from the embodiment 1 is that difference in the offset direction of the leads 7 and the direction of the device formation surface of the semiconductor chip 2. As shown in FIGS. 27 and 28, the semiconductor chip 2 of the embodiment 2 is installed in the semiconductor device 1 while the surface of the semiconductor chip 2 opposite to the device formation surface (non device formation surface) faces toward the rear surface side of the semiconductor device 1, i.e., the solder bump 9 side (hereinafter referred to as face up).

That is, the semiconductor device 1 of the embodiment 2 has a structure where the leads 7 projecting into the device hole of the wiring substrate 4 respectively have a first bend portion 15 bend-processed toward the front surface side of the semiconductor device 1 (the side where the stiffener 3 of the wiring substrate 4 is formed), a second bend portion 16 bend-processed so as to form a connection portion parallel to the device formation surface of the semiconductor chip 2 on the lead tip side from the first bend portion 15. In this structure, the connection surface between the leads 7 and the semiconductor chip 2 is positioned on the front surface side of the semiconductor device 1 from the plane where the leads 7 project, i.e., the side where the stiffener 3 is formed, or in other words, in a direction away from the connection between the semiconductor chip and the leads, and the leads 7 are connected to the faced-up semiconductor chip 2.

At this time, it is significant to control the offset amount of the leads 7 such that the position of the non device formation surface of the semiconductor chip 2 connected to the leads 7 is not lower than the lowest point of the solder bumps 9, as shown in FIG. 27.

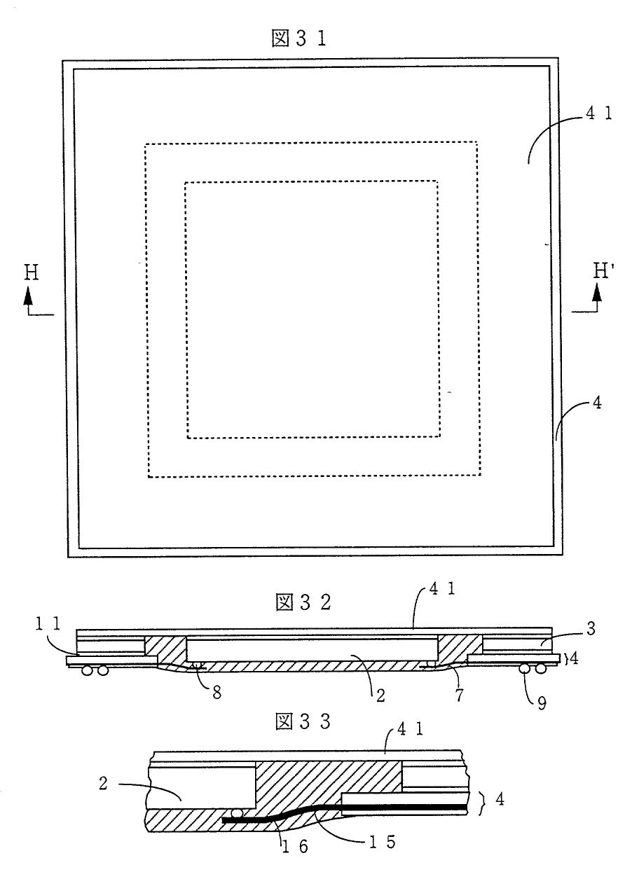

Next, FIG. 29 shows an example where the semiconductor device 1 of the embodiment 2 is packaged on a print substrate. The semiconductor device 1 of the embodiment 2 is packaged with a QFP-type semiconductor device on the surface of a print substrate 40.

Next, an example of a method for manufacturing the semiconductor device of the embodiment 2 will be described in accordance with the flowchart of FIG. 30.

First, prior to the manufacture of the semiconductor device, the tape 19, the stiffeners 3, the semiconductor chips 2, the sealing resin, the flux, the solder bumps and the like are prepared, similarly to the embodiment 1.

Next, at the lead offset process, the leads 7 of the tape 19 are pressed into a predetermined shape by the die and punch, and cut to have a length appropriate to the semiconductor chip by the cutting punch, similarly to the embodiment 1 (process a).

Next, at the stiffener 3 attachment process, the stiffener 9 is attached via the adhesive 11 by heat pressing around the device hole on the substrate 10 of the tape 19, processed at the lead offset process (process b).

Next, at the Au bump 8 formation process, the Au bumps 8 are formed by, e.g., ball bonding, on the pads formed on one main surface of the semiconductor chip 2. The formation of the bumps may be made by plating (process c).

Next, at the lead bonding process, the semiconductor chip 2 is mounted on the bonding stage, while the main surface of the semiconductor chip 2 and the photosensitive insulating film side of the tape 19 are opposite to each other, then, the bonding tool is struck vertically toward the main surface side of the semiconductor chip 2, to connect the Au bumps 8 of the semiconductor chip 2 to the leads 7 of the tape 19 by heat-pressing (process d).

Next, at the resin sealing process, the main surface of the semiconductor chip 2 where the integrated circuit is formed, the side surfaces and the leads 7 are sealed by the sealing resin 5 (process e).

Next, at the solder bump formation process, ball-shaped bumps of Pb—Sn or the like are connected to the bump lands exposed through the openings formed in the photosensitive insulating film of the tape 19, thus forming the solder bumps as external electrodes of the semiconductor device (process f).

Next, at the cutting process, the band-shape tape 19 is cut at a position slightly outer from the periphery of the stiffener 3. Thus, the semiconductor device is cut out as one piece (process g).

Thereafter, a predetermined examination is performed on the semiconductor device 1 to determine whether it is good/no good. Thus, the manufacture of the semiconductor devices is completed.

According to the embodiment 2 as described above, effects similar to those described in the embodiment 1 is obtained, i.e., the semiconductor 1 can be constructed to have the structure where the position of the semiconductor chip 2 viewed from the side surface of the semiconductor device 1 can be as center as possible of the semiconductor device 1, then the total thickness of the solder bumps 9, the wiring substrate 4, the leads 7 on the wiring substrate 4, the stiffener 3 and the adhesive 11 includes the semiconductor chip 2, the Au bumps 8 and the leads 7 connected to the Au bumps 8. Accordingly, a thin semiconductor device for multi-pin design can be obtained.

This embodiment also obtains effects similar to effects (2) to (8) described in the other example of the embodiment 1.

(Embodiment 3)

The structure of the semiconductor device of an embodiment 3 and the method for manufacturing the semiconductor device will be described by using FIGS. 31 to 35. The semiconductor device of the embodiment 3 is a BGA type semiconductor device where the leads 7 on the tape wiring substrate 4 are offset processed, similarly to the embodiment 1 and the embodiment 2. The feature of the embodiment 3 is that a radiation plate 41 for improving a thermal characteristic is provided in the semiconductor device 1.

That is, the wiring substrate 4, similar to that of the embodiment 1, has a device hole formed at its center through the wiring substrate 4, and the device hole is capable of containing the semiconductor chip. Further, the plurality of leads 7 of copper foil project into the device hole. The leads 7 respectively have a first bend portion 15 bend-processed toward the rear surface side of the semiconductor device 1, i.e., the side where the solder bumps 9 are formed, and a second bend portion 16 bend-processed so as to form a connection portion parallel to the device formation surface of the semiconductor chip 2, on the lead end side from the first bend portion 15.

The connection portions of the offset-processed leads 7 are connected to the faced-down semiconductor chip 2.

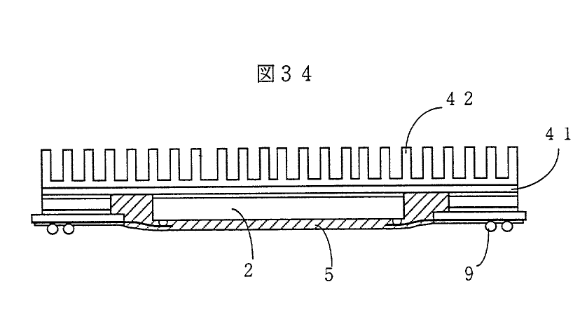

The radiation plate 41 is formed on the upper surface of the stiffener 3 of the wiring substrate 4 and on the non device formation surface of the semiconductor chip. To mount the radiation plate 41, the non device formation surface of the semiconductor chip 2 and the upper surface of the stiffener 3 must be positioned within the same plane. For example, in the embodiment 3, in consideration of the diameter of the solder bumps 9, the offset amount of the leads 7 is set to 125 μm such that the position of the semiconductor chip 2 is as center as possible of the semiconductor device 1. This structure attains thinning and improves the radiation characteristic. The offset amount is not necessarily limited to this amount. As shown in FIGS. 32 and 33, the offset amount may be any value as long as the non device formation surface of the semiconductor chip 2 and the upper surface of the stiffener 3 are positioned within substantially the same plane.

The radiation plate is attached on the non device formation surface of the semiconductor chip 2 and the upper surface of the stiffener 3 by adhesive of epoxy resin. Further, the material of the radiation plate is preferably copper tungsten (Cu—W) which is material having a thermal expansion coefficient close to that of the semiconductor chip 2, however, another material such as an Fe alloy, mullite, aluminum nitride, or carbon material e.g. diamond may be used.

The radiation plate 41 greatly contributes to efficient radiation of heat caused at the semiconductor chip 2 toward the outside the semiconductor device, thus improves operation reliability and life of the semiconductor device 1.

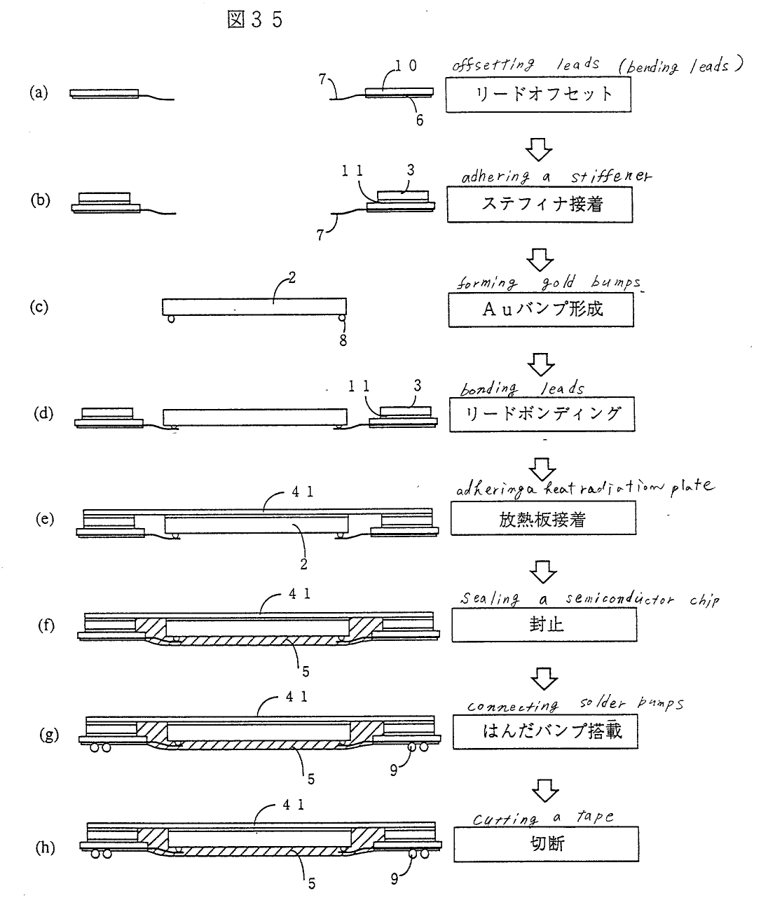

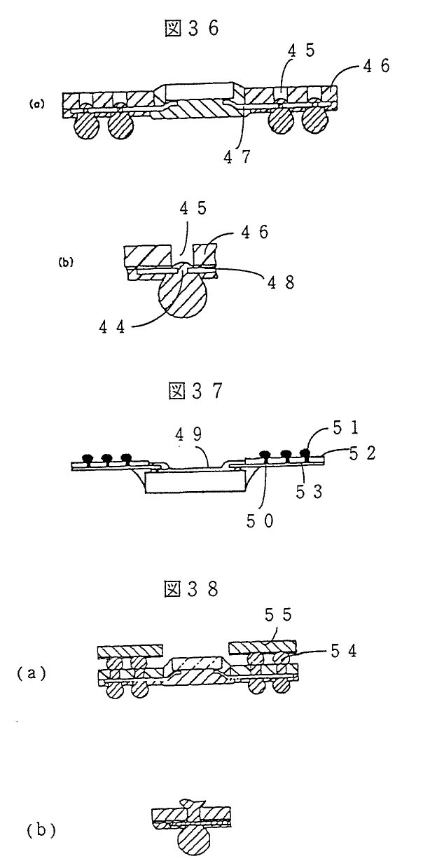

Further, as shown in FIG. 34, radiation fins 42, corresponding to a semiconductor device which generates higher heat, may be mounted on the radiation plate 41. The material of the radiation fins 42 is preferably aluminum, and the shape of the fins is a shape to increase the surface area and improve the radiation characteristic of the plate. The material and shape are not necessarily limited to these material and shape, but may be selected in consideration of optimization of the semiconductor chip.

The main surface of the semiconductor chip where the integrated circuit is formed, the side surfaces and the leads are sealed by sealing resin for the purposes of protection and improvement of moisture resistance, and improvement of the reliability in the junction portion between the leads and the semiconductor chip. As the resin, silicone resin, epoxy resin or the like is employed.

The ball-shaped solder bumps 9 are provided as terminals for connection with the packaging substrate, along the outer periphery of the tape wiring substrate 4 in two lines, a periphery-side line and an inner line.

Hereinafter, a method for manufacturing the semiconductor device of the embodiment 3 will be described in accordance with the flowchart of FIG. 35.

First, prior to the manufacture of the semiconductor device, the tape, the stiffeners, the semiconductor chips, the sealing resin, the flux, the solder balls, the radiation plates and the like are prepared.

Next, at the lead offset process, the leads of the tape 19 are pressed into a predetermined shape by the die and punch, and cut to have a length appropriate to the semiconductor chip by the cutting punch, similarly to the embodiment 1 (process a).

Next, at the stiffener attachment process, the stiffener 3 is attached via the adhesive 11 of epoxy resin or the like by heat pressing around the device hole on the substrate 10 of the tape 19, processed at the lead offset process (process b).

Next, at the Au bump formation process, the Au bumps 8 are formed by, e.g., ball bonding, on the pads formed on one main surface of the semiconductor chip. The formation of the bumps may be made by plating (process c).

Next, at the lead bonding process, the semiconductor chip 2 is mounted on the bonding stage, while the main surface of the semiconductor chip 2 and the photosensitive insulating film side of the tape 19 are opposite to each other, then, the bonding tool is struck vertically toward the main surface side of the semiconductor chip 2, to connect the Au bumps 8 of the semiconductor chip 2 to the leads 7 by heat-pressing (process d).

Next, the radiation plate is attached via the adhesive of epoxy resin or the like, on the non device formation surface of the semiconductor chip 2 and the upper surface of the stiffener 3 (process e).

Next, at the resin sealing process, the main surface of the semiconductor chip where the integrated circuit is formed, the side surfaces and the leads are sealed by the sealing resin (process f).

Next, at the solder bump formation process, ball-shaped bumps of Pb—Sn or the like are connected to the bump lands exposed through the openings formed in the solder resist of the tape 19, thus forming the solder bumps as external electrodes of the semiconductor device (process g).

Next, at the cutting process, the band-shape tape 19 is cut at a position slightly outer from the periphery of the stiffener 3. Thus, the semiconductor device is cut out as one piece (process h).

Thereafter, a predetermined examination is performed on the semiconductor device 1 to determine whether it is good/no good. Thus, the manufacture of the semiconductor devices is completed.

According to the embodiment 3 as described above, effects similar to effects (1) to (7) described in the embodiment 1 are obtained.

Further, as effect (8), by mounting the radiation plate and radiation fins, the thermal resistance becomes ½ of the case where the device is manufactured without those parts, thus the radiation characteristic of the semiconductor device can be greatly improved.

The present invention made by the present inventor as described above is not limited to the above embodiments, and various changes can be made within the scope of the present invention.

### INDUSTRIAL APPLICABILITY

As described above, the semiconductor device according to the present invention is effectively applicable to a BGA-type semiconductor device, further to a small memory card using the BGA-type semiconductor device, a portable device such as a handy-type personal computer, a small information processing device, and the like.

1. A semiconductor device comprising a semiconductor chip, a wiring substrate provided surrounding the semiconductor chip, leads projected from the wiring substrate and connected to said semiconductor chip, a stiffening member provided on one main surface of said wiring substrate, surrounding said semiconductor chip, a plurality of bumps provided along a periphery of said wiring substrate on an opposite main surface of said wiring substrate to the main surface where said stiffening member is provided, and resin covering said semiconductor chip and the leads, wherein the leads connected to said semiconductor chip are bend-processed toward a side where the stiffening member of said wiring substrate is provided or a side where the plurality of bumps are formed, and wherein said leads and said semiconductor chip are connected such that a surface of said semiconductor chip opposite to the surface connected to said leads is positioned on a side opposite to the side where said leads are bend-processed

2. The semiconductor device according to claim 1, wherein said leads are bend-processed toward the side where said plurality of bumps are provided.

3. The semiconductor device according to claim 1, wherein said leads are bend-processed toward the side where the stiffening member of said wiring substrate is provided.

4. The semiconductor device according to any one of claims 1 to 3, wherein the bend-processed leads have a first bend portion bend-processed in a direction away from the surface of said semiconductor chip connected to the leads, and a second bend portion bend-processed on a lead end side from the first bend portion.

5. The semiconductor device according to any one of claims 1 to 4, wherein a photosensitive insulating film is formed on the side of said wiring substrate where the plurality of bumps are provided.

6. The semiconductor device according to any one of claims 1 to 5, wherein said plurality of bumps are provided in a plurality of lines.

7. A semiconductor device comprising a semiconductor chip, a wiring substrate provided surrounding the semiconductor chip, leads projected from the wiring substrate and connected to said semiconductor chip, a stiffening member provided on one main surface of said wiring substrate, surrounding said semiconductor chip, a plurality of bumps provided along a periphery of said wiring substrate on an opposite main surface of said wiring substrate to the main surface where said stiffening member is provided, and resin covering said semiconductor chip and the leads, wherein the total thickness of said wiring substrate, the stiffening member and the plurality of bumps includes said semiconductor chip and the resin.

8. The semiconductor device according to claim 7, wherein the surface of said semiconductor chip connected to said leads faces toward a side where said plurality of bumps are provided.

9. The semiconductor device according to claim 7, wherein the surface of said semiconductor chip connected to said leads faces toward a side where said stiffening member is provided.

10. A semiconductor device comprising a semiconductor chip, a wiring substrate provided surrounding the semiconductor chip, a stiffening member provided on one main surface of said wiring substrate, surrounding said semiconductor chip, a plurality of bumps provided along a periphery of said wiring substrate on an opposite main surface of said wiring substrate to the main surface where said stiffening member is provided, leads projected from the wiring substrate and connected to said semiconductor chip, and resin covering said semiconductor chip and the leads, wherein said leads are bend-processed toward a side where said plurality of bumps are provided, and wherein an another surface of said semiconductor chip opposite to the surface connected to said leads is positioned on a side where said stiffening member is provided, further wherein a radiation plate is connected to the other surface of said semiconductor chip and the surface of said stiffening member.

11. The semiconductor device according to claim 10, wherein radiation fins are connected to said radiation plate.

12. A semiconductor device comprising a frame-shaped wiring substrate, a plurality of bumps formed on one surface of the wiring substrate, a stiffening member formed on another surface of said wiring substrate, a plurality of leads projected from said wiring substrate and offset-processed toward a side where said plurality of bumps are formed, a semiconductor chip connected to said plurality of leads such that a non device formation surface is positioned in a direction opposite to an offset direction of said plurality of offset-processed leads, and resin covering said semiconductor chip and said plurality of leads.

13. A semiconductor device comprising a frame-shaped wiring substrate, a plurality of bumps formed on one surface of the wiring substrate, a stiffening member formed on another surface of said wiring substrate, a plurality of leads projected from said wiring substrate and offset-processed toward a side where said stiffening member is formed, a semiconductor chip connected to said plurality of leads such that a non device formation surface is positioned in a direction opposite to an offset direction of said plurality of offset-processed leads, and resin covering said semiconductor chip and said plurality of leads.

14. A semiconductor-device manufacturing method comprising a step of preparing a band-shaped tape having a resin substrate, a device hole provided in the resin substrate and copper-foil leads projecting into the device hole and bend-processed,-and a stiffening member connected to one main surface of said tape, surrounding said device hole, a step of connecting said leads, projecting into the device hole of said tape and bend-processed, to one main surface of a semiconductor chip, a step of sealing said semiconductor chip and the leads with resin, a step of connecting a plurality of bumps to another main surface of said tape opposite to the main surface where said stiffening member is connected.

15. The semiconductor-device manufacturing method according to claim 14, wherein said tape has leads bend-processed toward a side of said stiffening member, and wherein said semiconductor chip is connected to said leads such that a surface opposite to the surface connected to said leads is positioned on a side of said plurality of bumps.

16. The semiconductor-device manufacturing method according to claim 14, wherein said tape has leads bend-processed toward a side of said plurality of bumps, and wherein said semiconductor chip is connected to said leads such that a surface opposite to the surface connected to said leads is positioned on a side of said stiffening member.

17. A packaging structure, comprising a print substrate having a main surface and another main surface opposite to the main surface, for packaging a plurality of semiconductor devices on the main surface and the other main surface of the print substrate, wherein a semiconductor device comprising a semiconductor chip, a wiring substrate provided surrounding the semiconductor chip, leads projected from the wiring substrate and connected to said semiconductor chip, a stiffening member provided on the one main surface of said wiring substrate, surrounding said semiconductor chip, a plurality of bumps provided along a periphery of said wiring substrate on the other main surface of said wiring substrate opposite to the main surface where said stiffening member is provided, and resin covering said semiconductor chip and the leads, is packaged on said main surface, such that the total thickness of said wiring substrate, the stiffening member and the plurality of bumps includes said semiconductor chip and the resin.

18. The packaging structure according to claim 17, wherein said semiconductor device has a function of a microcomputer and/or a function of a gate array.

19. The packaging structure according to claim 17, wherein another semiconductor device packaged on said print substrate is of TCP type, TSOP type or UTSOP type.

20. The packaging structure according to claim 19, wherein said other semiconductor device is a memory.

21. The packaging structure according to claim 17, wherein said packaging structure is used in a memory card.

22. A packaging structure, comprising a print substrate having a main surface, and a plurality of semiconductor devices packaged on the main surface, wherein in one of the plurality of semiconductor devices, comprising a semiconductor chip, a wiring substrate provided surrounding the semiconductor chip, leads projected from the wiring substrate and connected to said semiconductor chip, a stiffening member provided on one main surface of said wiring substrate, surrounding said semiconductor chip, a plurality of bumps provided along a periphery of said wiring substrate on an opposite main surface of said wiring substrate to the main surface where said stiffening member is provided, and resin covering said semiconductor chip and the leads, the total thickness of said wiring substrate, the stiffening member and the plurality of bumps includes said semiconductor chip and the resin, and wherein another semiconductor is a QFP-type semiconductor device.

23. The packaging structure according to claim 22, wherein said other semiconductor device is of TCP type or TSOP type.

24. The packaging structure according to claim 22, wherein said packaging structure is used in a multimedia device.
